(19) United States
(12) Patent Application Publication
(10) Pub. No.: US 2024/0013710 A1
(43) Pub. Date: Jan. 11, 2024

(54) DISPLAY DEVICE AND PIXEL LIGHTING CONTROL METHOD THEREFOR

(71) Applicant: TCL TECHNOLOGY GROUP CORPORATION, Huizhou (CN)

(72) Inventors: Wenjun HOU, Huizhou (CN); Yixing YANG, Huizhou (CN)

(21) Appl. No.: 18/260,159

(22) PCT Filed: Dec. 29, 2021
(86) PCT No.: PCT/CN2021/142445

§ 371 Date: Jun. 30, 2023

(30) Foreign Application Priority Data
Dec. 31, 2020 (CN) 202011639732.7

(51) Int. Cl. G09G 3/32; H10K 59/35

(52) U.S. Cl. CPC G09G 3/32; H10K 59/351; G09G 2320/045; G09G 2300/0443; G09G 2300/0452

(57) ABSTRACT

Disclosed are a display device and a pixel lighting control method therefor. The display device comprises a plurality of pixels arranged in an array, each pixel comprises a red light sub-pixel, a green light sub-pixel, a first blue light sub-pixel and a second blue light sub-pixel arranged in an array. The display device further comprises: a starting module configured to start the first blue light sub-pixel to emit light when a target blue light brightness value is greater than a preset blue light brightness value, and start the second blue light sub-pixel to emit light when the target blue light brightness value is lower than the preset blue light brightness value. In this way, by selecting blue light quantum dot devices with different characteristics, both high luminous efficiency and long lifetime of the device can be realized without affecting the display effect of the full-color display device.

### CROSS-REFERENCE TO RELATED APPLICATIONS

The present application claims priority to Chinese patent application NO. 202011639732.7, titled “Display device and pixel lighting control method therefor”, and filed on Dec. 31, 2020, all of which is herein incorporated by reference.

### TECHNICAL FIELD

The present disclosure relates to the technical field of display devices, in particular to a display device and a pixel lighting control method therefor.

### BACKGROUND

Due to the unique optoelectronic property of quantum dots, such as emission wavelength being continuously tunable with size and composition, narrow emission spectra, high fluorescence efficiency, and good stability, quantum dot-based light-emitting diode (QLED) has attracted extensive attention and research in the display field. In addition, QLED display offers advantages that LCD cannot achieve, such as wider viewing angle, higher contrast, shorter response times, and flexibility, making QLED a promising next-generation display technology.

QLED device operate by injecting electrons and holes. The simplest QLED device consists of a cathode, an electron transport layer, a quantum dot emission layer, a hole transport layer, and an anode. In the QLED device, the quantum dot emission layer is sandwiched between charge transport layers. When a forward bias is applied to the QLED device, electrons and holes enter the quantum dot emission layer through the electron transport layer and the hole transport layer, respectively, leading to recombination and emission of light.

After more than two decades of development, quantum dot materials have made significant progress, and remarkable improvement in external quantum efficiency in red light, green light, and blue light QLED devices, particularly in devices based on CdSe. The enhancement in QLED device efficiency highlights its future prospects. Currently, the quantum efficiencies of red light and green light quantum dot devices are both above 20%, and their device lifetimes have reached the level of commercialization, comparable to red light and green light OLED devices. However, when compared to blue light OLED device, the blue light quantum dot device still faces significant challenges in achieving both high efficiency and long lifetimes.

Therefore, the prior art still needs to be improved and developed.

### SUMMARY

In view of the deficiencies in the prior art above, the purpose of the present disclosure is to provide a display device and a pixel lighting control method therefor, aiming at solving the problem that the existing blue light quantum dot device is difficult to achieve high efficiency and long lifetime at the same time.

The disclosed technical scheme is as follows:

A display device, which includes a plurality of pixels arranged in an array, each pixel includes a red light sub-pixel, a green light sub-pixel, a first blue light sub-pixel and a second blue light sub-pixel arranged in an array;

The display device further includes: a starting module, configured to start the first blue light sub-pixel to emit light when a target blue light brightness value is greater than a preset blue light brightness value, and start the second blue light sub-pixel to emit light when the target blue light brightness value is lower than the preset blue light brightness value.

Optionally, a current efficiency of the first blue light sub-pixel is ≥8 cd/A, and/or, a ratio of the current efficiency of the first blue light sub-pixel to a current efficiency of the second blue light sub-pixel is ≥1.5;

And/or, a lifetime of the second blue light sub-pixel is ≥200 h@1000 nits, and/or, a ratio of the lifetime of the second blue light sub-pixel to a lifetime of the first blue light sub-pixel is ≥1.5.

Optionally, the ratio of the current efficiency of the first blue light sub-pixel to the current efficiency of the second blue light sub-pixel is greater than or equal to 1.5 and less than 3;

And/or, the ratio of the lifetime of the second blue light sub-pixel to the lifetime of the first blue light sub-pixel is greater than or equal to 1.5 and less than 3.

Optionally, the display device also includes:
A comparison module, the comparison module is configured to compare a required blue light brightness with the preset blue light brightness value;
A control module, the control module is configured to control the first blue light sub-pixel or the second blue light sub-pixel to emit light according to a comparison result.

Optionally, the control module is a multiplexer.

Optionally, the red light sub-pixel includes a first anode, a first hole injection layer, a first hole transport layer, a red light quantum dot light-emitting layer, a first electron transport layer, a first cathode, and a light extraction layer stacked sequentially.

The green light sub-pixel includes a second anode, a second hole injection layer, a second hole transport layer, a green light quantum dot light-emitting layer, a second electron transport layer, a second cathode, and a second light extraction layer stacked sequentially.

The first blue light sub-pixel includes a third anode, a third hole injection layer, a third hole transport layer, a first blue light quantum dot light-emitting layer, a third electron transport layer, a third cathode and a third light extraction layer stacked sequentially;

The second blue light sub-pixel includes a fourth anode, a fourth hole injection layer, a fourth hole transport layer, a second blue light quantum dot light-emitting layer, a fourth electron transport layer, a fourth cathode and a fourth light extraction layer stacked sequentially.

Optionally, an emission wavelength of a red light quantum dot is 610-625 nm, and/or an emission wavelength of a green light quantum dot is 525-550 nm, and/or an emission wavelength of a first blue light quantum dot is 450-480 nm, and/or an emission wavelength of a second blue light quantum dot is 450-480 nm.

A pixel lighting control method for the display device, the display device includes a plurality of pixels arranged in an array, and each pixel includes a red light sub-pixel, a green light sub-pixel, a first blue light sub-pixel and a second blue light sub-pixel arranged in an array, and the control method includes:

Controlling the first blue light sub-pixel or the second blue light sub-pixel to emit light according to the target blue light brightness value and the preset blue light brightness value.

Optionally, the step of controlling the first blue light sub-pixel or the second blue light sub-pixel to emit light according to the target blue light brightness value and the preset blue light brightness value includes:
Starting the first blue light sub-pixel to emit light when the target blue light brightness value is greater than or equal to the preset blue light brightness value; or,
Starting the second blue light sub-pixel to emit light when the target blue light brightness value is lower than the preset blue light brightness value.

Optionally, the current efficiency of the first blue light sub-pixel is ≥8 cd/A, and/or, the ratio of the current efficiency of the first blue light sub-pixel to the current efficiency of the second blue light sub-pixel is greater than or equal to 1.5 and less than 3;

And/or, the lifetime of the second blue light sub-pixel is ≥200 h@1000 nits, and/or, the ratio of the lifetime of the second blue light sub-pixel to the lifetime of the first blue light sub-pixel is greater than or equal to 1.5 and less than 3.

Beneficial effects: the present disclosure provides a full-color display device. In the device, the first blue light sub-pixel is a high-efficiency blue light quantum dot device, which is lighted when high brightness is required; the second blue light sub-pixel is a long-lifetime blue light quantum dot device, which is lighted up when low brightness is required. In this way, by selecting blue light quantum dot devices with different characteristics, high luminous efficiency and long lifetime of the device can be realized without affecting the display effect of the full-color display device.

### BRIEF DESCRIPTION OF THE DRAWINGS

FIG. 1 is a schematic diagram of a multiplexer respectively connected to sub-pixels B1 and B2 provided by an embodiment of the present disclosure.

FIG. 2 is a schematic structural diagram of a display device provided by an embodiment of the present disclosure.

FIG. 3 is a schematic flowchart of a method for manufacturing the display device provided by an embodiment of the present disclosure.

FIG. 4 is a schematic diagram of the structure obtained through step S11 in FIG. 3.

FIG. 5 is a schematic diagram of the structure obtained through step S12 in FIG. 3.

FIG. 6 is a schematic diagram of the structure obtained through step S13 in FIG. 3.

FIG. 7 is a schematic diagram of the structure obtained through step S14 in FIG. 3.

FIG. 8 is a schematic diagram of the structure obtained through step S15 in FIG. 3.

FIG. 9 is a schematic diagram of the structure obtained through step S16 in FIG. 3.

### DETAILED DESCRIPTION OF THE EMBODIMENTS

The present disclosure provides a display device and a pixel lighting control method therefor. In order to make the purpose, technical solution and effect of the present disclosure clearer, the present disclosure will be further described in detail below. It should be understood that the embodiments described here are only configured to explain the present disclosure, not to limit the present disclosure.

Existing blue light quantum dots either have high luminous efficiency but short lifetime, or long lifetime but low luminous efficiency. Therefore, the existing blue light quantum dots cannot meet the requirements for device efficiency and lifetime at the same time.

Based on this, an embodiment of the present disclosure provides a display device, which comprises a plurality of pixels arranged in an array, and each pixel comprises a red light sub-pixel, a green light sub-pixel, a first blue light sub-pixel and a second blue light sub-pixel arranged in an array;

The display device also comprises: a starting module, the starting module is configured to start the first blue light sub-pixel to emit light when a target blue light brightness value is greater than a preset blue light brightness value, and start the second blue light sub-pixel to emit light when the target blue light brightness value is lower than the preset blue light brightness value.

In the present embodiment, the first blue light sub-pixel has a high luminous efficiency, and the second blue light sub-pixel has a long lifetime. When a required blue light brightness (i.e., the target blue light brightness value) is greater than or equal to the preset blue light brightness value, the first blue light sub-pixel is started to emit light; otherwise, when the required blue light brightness is less than the preset blue light brightness value, the second blue light sub-pixel is started to emit light. It should be noted that the preset blue light brightness value refers to 70%-90% of the highest blue light brightness value of the product. For example, when the display device is applied to TV, and the normal brightness of TV products is 100 nits, the range of the preset blue light brightness value is 70-90 nits.

In the present embodiment, the display device comprises a plurality of pixels, each pixel comprises four sub-pixels, and the four sub-pixels comprise a red light sub-pixel (R sub-pixel), a green light sub-pixel (G sub-pixel), a first blue light sub-pixel (B1 sub-pixel) and a second blue light sub-pixel (B2 sub-pixel). In the present embodiment, each pixel is composed of the R sub-pixel, the G sub-pixel, the B1 sub-pixel and the B2 sub-pixel, based on the three primary colors of R, G, and B, the full-color display of the device is realized. In the four sub-pixels of R, G, B1 and B2 arranged in an array, each sub-pixel is lighted by independent driving, and independently driven by a driving circuit to emit light.

In the present embodiment, the R, G, B1, and B2 sub-pixels are all quantum dot-based electroluminescent devices, therein the B1 sub-pixel is a high-efficiency blue light quantum dot device, which is lighted when high brightness is required; the B2 sub-pixel is long-lifetime blue light quantum dot devices, which is lighted when low brightness is required. In this way, by selecting blue light quantum dot devices with different characteristics, both high luminous efficiency and long lifetime of the device can be realized without affecting the display effect of the full-color display device.

In the present embodiment, the B1 sub-pixel is a high-efficiency blue light quantum dot device. In one embodiment, the current efficiency of the first blue light sub-pixel (denoted as C.E._{B1}) is ≥8 cd/A, that is, C.E._{B1}≥8 cd/A.

In one embodiment, the ratio of the current efficiency of the first blue light sub-pixel to the current efficiency of the second blue light sub-pixel (denoted as C.E._{B2}) is ≥1.5, that is, C.E._{B1}/C.E._{B2}≥1.5. In one embodiment, 3≥C.E._{B1}/C.E._{B2}≥1.5.

In the present embodiment, the B2 sub-pixel is a long-lifetime blue light quantum dot device. In one embodiment, the lifetime of the second blue light sub-pixel (denoted as L.T._{B2}) is ≥200 h@1000 nits, that is, L.T._{B2}≥200 h@1000 nits.

In one embodiment, the ratio of the lifetime of the second blue light sub-pixel to the lifetime of the first blue light sub-pixel (denoted as L.T._{B1}) is ≥1.5, that is, L.T._{B2}/L.T._{B1}≥1.5. In one embodiment, 3≥L.T._{B2}/L.T._{B1}≥1.5.

It should be noted that there are many existing materials and structures optimized for quantum dot devices, including the selection of core/shell quantum dot materials and alloyed interface to reduce surface defects and suppress the Auger process; the design of surface ligands and optimized charge transport layer, etc., to improve the luminous efficiency and prolong lifetime. Therefore, by optimizing the material or structure of the quantum dot device, the first blue light sub-pixel with high luminous efficiency can be obtained, and the second blue light sub-pixel with long lifetime can also be obtained.

In one embodiment, the display device further comprises:
A comparison module, the comparison module is configured to compare a target blue light brightness value with a preset blue light brightness value;
A control module, the control module is configured to control the first blue light sub-pixel or the second blue light sub-pixel to emit light according to a comparison result.

In the present embodiment, when the comparison result shows that a required blue light brightness value is greater than or equal to the preset blue light brightness value, the control module controls the first blue light sub-pixel to emit light; otherwise, when the comparison result shows that the required blue light brightness value is less than the preset blue light brightness value, the control module controls the second blue light sub-pixel to emit light.

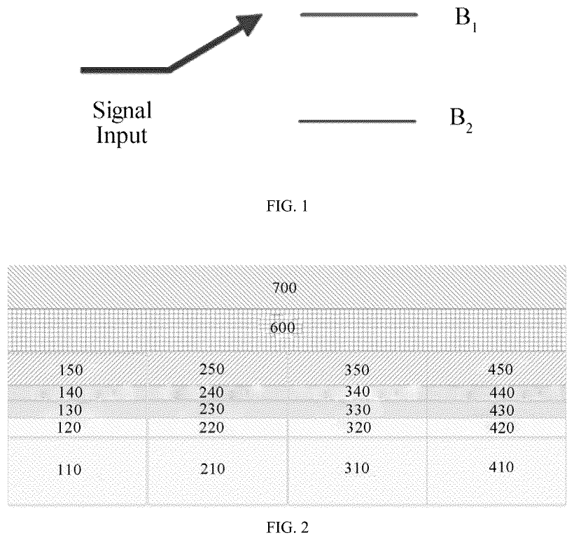

In one embodiment, the control module is a multiplexer (MUX for short), or called a data selector. The multiplexer is a device that can select one signal from multiple analog or digital input signals for output. The multiplexer used in the present embodiment is the simplest 2-to-1 multiplexer, and the function is similar to a bidirectional selection switch. The multiplexer is connected to the B1 and B2 sub-pixels respectively, as shown in FIG. 1. During operation, the B1 or B2 sub-pixels are selectively lighted according to the brightness requirement. There is no need to add other structural units, only a multiplexer is needed to be integrated between the conventional chip and the driving circuit of the display panel.

In one embodiment, the red light sub-pixel comprises a first anode, a red light quantum dot light-emitting layer, and a first cathode that are stacked sequentially; further, the red light sub-pixel comprises a first anode, a first hole injection layer, a first hole transport layer, a red light quantum dot light-emitting layer, a first electron transport layer, a first cathode and a first light extraction layer that are stacked sequentially;

The green light sub-pixel comprises a second anode, a green light quantum dot light-emitting layer, and a second cathode that are stacked sequentially; further, the green light sub-pixel comprises a second anode, a second hole injection layer, a second hole transport layer, a green light quantum dot light-emitting layer, a second electron transport layer, a second cathode and a second light extraction layer that are stacked sequentially.

The first blue light sub-pixel comprises a third anode, a first blue light quantum dot light-emitting layer and a third cathode that are stacked sequentially; further, the first blue light sub-pixel comprises a third anode, a third hole injection layer, a third hole transport layer, a first blue light quantum dot light-emitting layer, a third electron transport layer, a third cathode and a third light extraction layer that are stacked sequentially;

The second blue light sub-pixel comprises a fourth anode, a second blue light quantum dot light-emitting layer and a fourth cathode that are stacked sequentially; further, the second blue light sub-pixel comprises a fourth anode, a fourth hole injection layer, a fourth hole transport layer, a second blue light quantum dot light-emitting layer, a fourth electron transport layer, a fourth cathode and a fourth light extraction layer that are stacked sequentially.

In the present embodiment, each sub-pixel has multiple forms, and each sub-pixel has a forward structure and a reverse structure. When the anode is on the substrate, the sub-pixel is having a forward structure; and when the cathode is on the substrate, the sub-pixel is having a reverse structure. The present embodiment mainly introduces the structure shown in FIG. 2 in detail. As shown in FIG. 2, the display device of the present embodiment comprises a plurality of pixels arranged in an array, and each pixel is composed of a red light sub-pixel, a green light sub-pixel, a first blue light sub-pixel and a second blue light sub-pixel.

The red light sub-pixel comprises an anode (Anode), a hole injection layer (HIL), a hole transport layer (HTL), a red light quantum dot light-emitting layer (EML, red light QD), an electron transport layer (ETL), a cathode (Cathode) and a light extraction layer (CPL) that are stacked sequentially.

The green light sub-pixel comprises an anode (anode), a hole injection layer (HIL), a hole transport layer (HTL), a green light quantum dot light-emitting layer (EML, green light QD), an electron transport layer (ETL), a cathode (Cathode) and a light extraction layer (CPL) that are stacked sequentially.

The first blue light sub-pixel comprises an anode (Anode), a hole injection layer (HIL), a hole transport layer (HTL), a first blue light quantum dot light-emitting layer (EML, blue light QD1), an electron transport layer (ETL), a cathode (Cathode) and a light extraction layer (CPL) that are stacked sequentially.

The second blue light sub-pixel comprises an anode (Anode), a hole injection layer (HIL), a hole transport layer (HTL), a second blue light quantum dot light-emitting layer (EML, blue light QD2), an electron transport layer (ETL), a cathode (Cathode) and a light extraction layer (CPL) that are stacked sequentially.

In the present embodiment, the anode is a total reflection electrode, the cathode is a transmissive electrode, the light emitted by the display device is emitted from the cathode, and the light extraction layer is arranged on the cathode to increase the light extraction efficiency, thereby improving the luminous efficiency of the device. Of course, the anode can also be a transmissive electrode, and the cathode can be a total reflection electrode. The light emitted by the display device is emitted from the anode, and the light extraction layer is arranged on the anode to increase the light extraction efficiency, thereby improving the luminous efficiency of the device.

In one embodiment, the emission wavelength of the red light quantum dots is 610-625 nm, and/or the emission wavelength of the green light quantum dots is 525-550 nm, and/or the emission wavelength of the blue light quantum dots is 450-480 nm.

In one embodiment, the red light quantum dot light-emitting layer, the green light quantum dot light-emitting layer, the first blue light quantum dot light-emitting layer and the second blue light quantum dot light-emitting layer all have a thickness of 5 nm-50 nm.

In one embodiment, the red light quantum dots, green light quantum dots, first blue light quantum dots and second blue light quantum dots can be independently selected as one or more of a binary phase, a ternary phase, and a quaternary phase quantum dot. The binary phase quantum dot includes one or more of CdS, CdSe, CdTe, InP, AgS, PbS, PbSe, HgS, etc., and the ternary phase quantum dot includes one or more of ZnCdS, CuInS, ZnCdSe, ZnSeS, ZnCdTe, and PbSeS, etc., and the quaternary phase quantum dot includes one or more of ZnCdS/ZnSe, CuInS/ZnS, ZnCdSe/ZnS, CuInSeS, ZnCdTe/ZnS, PbSeS/ZnS, etc. The quantum dot can be cadmium-containing or cadmium-free. The quantum dot light-emitting layer of the material has the characteristics of wide excitation spectrum and continuous distribution, and high stability of emission spectrum.

In one embodiment, the anode is a total reflection electrode, and the material of the total reflection electrode can be one of Al, Ag, Mo, etc., and other metals or their alloy materials, but is not limited thereto. It should be noted that, in the embodiment of the present disclosure, ITO electrodes (transparent electrodes), such as ITO/Ag/ITO, may be arranged on both sides of the total reflection electrode, so as to reduce the work function of the electrode and facilitate charge injection. In one embodiment, the thickness of the total reflection electrode is greater than or equal to 80 nm, such as 80 nm-120 nm. In one embodiment, the thickness of the ITO electrode is 10 nm-20 nm.

In one embodiment, the material of the hole injection layer can be but not limited to one or two or more of: poly(3,4-ethylenedioxythiophene)-poly(styrenesulfonic acid) (PEDOT:PSS), CuPc, P3HT, transition metal oxide and transition metal chalcogenide. The transition metal oxide comprises one or two or more of NiOₓ, MoOₓ, WOₓ, CrOₓ, and CuO. The metal chalcogenide comprises one or two or more of MoSₓ, MoSeₓ, WSₓ, WSeₓ, and CuS. In one embodiment, the thickness of the hole injection layer is about 10 nm-40 nm.

In one embodiment, the material of the hole transport layer can be materials with good hole transport property, such as but not limited to one or more of poly(9,9-dioctylfluorene-CO—N-(4-butylphenyl)diphenylamine) (TFB), polyvinyl carbazole (PVK), poly(N,N′bis(4-butylphenyl)-N,N′-bis(phenyl)benzidine) (Poly-TPD), 4,4′,4″-tris(carbazol-9-yl)triphenylamine (TCTA), 4,4′-bis(9-carbazolyl)biphenyl (CBP), NPB, NiO, and MoO₃. In one embodiment, the thickness of the hole transport layer is about 10 nm-40 nm.

In one embodiment, the material of the electron transport layer can be conventional electron transport materials in the field, including but not limited to one of ZnO, MZO (magnesium zinc oxide), AMO (aluminum zinc oxide), MLZO (magnesium lithium zinc oxide), TiO₂, CsF, LiF, CsCO₃ and Alq3 or a mixture of any combination thereof. In one embodiment, the thickness of the electron transport layer is about 20 nm-50 nm.

In one embodiment, the cathode can be one of aluminum (Al) electrode, silver (Ag) electrode, and gold (Au) electrode, etc., and can also be one of nano-aluminum wire, nano-silver wire, and nano-gold wire, etc. The above-mentioned materials have relatively smaller resistance, so that carriers can be injected smoothly. In one embodiment, the thickness of the cathode is about 5 nm-40 nm.

In one embodiment, the material of the light extraction layer can be the same as that of the hole transport layer, such as CBP, etc.; it can also be the same as the material of the electron transport layer, such as LiF, etc.; it can also be o-phenanthroline and the derivatives thereof. In one embodiment, the thickness of the light extraction layer is about 30 nm-150 nm.

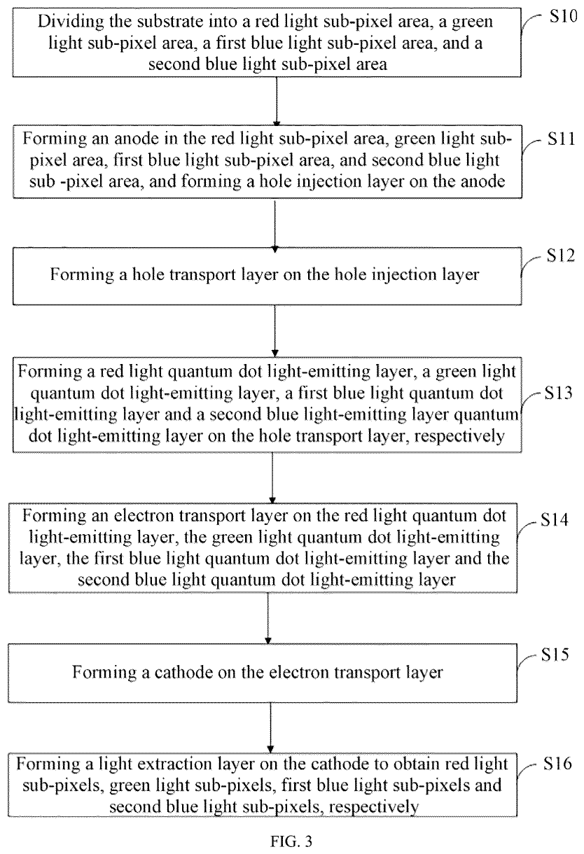

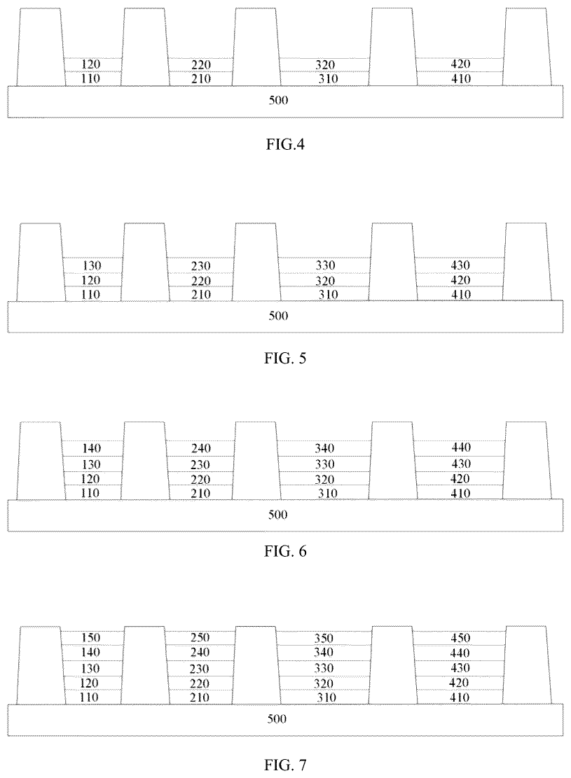

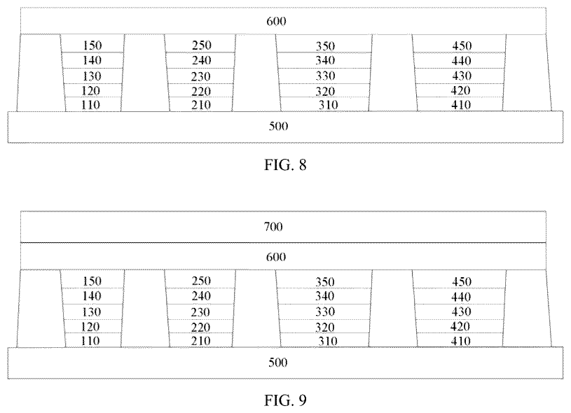

Taking the structure shown in FIG. 2 as an example, the preparation method for the display device is introduced. An embodiment of the present disclosure provides a method for manufacturing the display device. The display device comprises a plurality of pixels arranged in an array, and each pixel comprises a red light sub-pixel, a green light sub-pixel, a first blue light sub-pixel and a second blue light sub-pixel arranged in an array. The first blue light sub-pixel has high luminous efficiency, and the second blue light sub-pixel has a long lifetime. As shown in FIGS. 3-9, the preparation method for each pixel comprises steps of:
S10. Dividing the substrate into a red light sub-pixel area, a green light sub-pixel area, a first blue light sub-pixel area, and a second blue light sub-pixel area;
S11. Forming an anode (Anode) in the red light sub-pixel area, green light sub-pixel area, first blue light sub-pixel area, and second blue light sub-pixel area, and forming a hole injection layer (HIL) on the anode;
S12. Forming a hole transport layer (HTL) on the hole injection layer;
S13. Forming a red light quantum dot light-emitting layer (marked as R), a green light quantum dot light-emitting layer (marked as G), a first blue light quantum dot light-emitting layer (marked as B1) and a second blue light-emitting layer quantum dot light-emitting layer (marked as B2) on the hole transport layer, respectively;
S14. Forming an electron transport layer (ETL) on the red light quantum dot light-emitting layer, the green light quantum dot light-emitting layer, the first blue light quantum dot light-emitting layer and the second blue light quantum dot light-emitting layer;
S15. Forming a cathode (Cathode) on the electron transport layer;
S16. Forming a light extraction layer (CPL) on the cathode to obtain red light sub-pixels, green light sub-pixels, first blue light sub-pixels and second blue light sub-pixels, respectively.

In the present embodiment, when the blue light brightness value is required to be greater than or equal to the preset blue light brightness value, the first blue light sub-pixel is started to emit light;

On the contrary, when the blue light brightness value is required to be lower than the preset blue light brightness value, the second blue light sub-pixel is started to emit light. It should be noted that the preset blue light brightness value refers to 70%-90% of the highest blue light brightness value of the product. For example, when the display device is applied to TV, and the normal brightness value of TV product is 100 nits, the range of the preset blue light brightness value is 70-90 nits.

In the present embodiment, the display device comprises a plurality of pixels, and each pixel comprises four sub-pixels, and the four sub-pixels include a red light sub-pixel (R sub-pixel), a green light sub-pixel (G sub-pixel), a first blue light sub-pixel (B1 sub-pixel) and a second blue light sub-pixel (B2 sub-pixel). In the present embodiment, each pixel is composed of a R sub-pixel, a G sub-pixel, a B1 sub-pixel and a B2 sub-pixel, based on the three primary colors of R, G, and B, the full-color display of the device is realized. In the four sub-pixels of R, G, B1 and B2 arranged in an array, each sub-pixel is lighted by independent driving, and each sub-pixel is independently driven by a driving circuit to emit light.

In the present embodiment, the R, G, B1, and B2 sub-pixels are all quantum dot-based electroluminescent devices, therein the B1 sub-pixel is a high-efficiency blue light quantum dot device, which is lighted when high brightness is required; the B2 sub-pixel is a long-lifetime blue light quantum dot devices light up when low brightness is required. In this way, by selecting blue light quantum dot devices with different characteristics, both high luminous efficiency and long lifetime of the device can be realized without affecting the display effect of the full-color display device.

It should be noted that the method of preparing five dam-shaped pixel defining layers on the substrate divides the substrate into four sub-pixel areas. The materials and preparation of the pixel defining layer are known in the prior art and will not be described further herein.

For more details regarding the display device, please refer to the previous description, and it will not be reiterated here.

In the embodiment of the present disclosure, the aforementioned method for preparing each layer can be chemical method or physical method. The chemical method includes, but are not limited to, one or more of chemical vapor deposition, continuous ion layer adsorption and reaction, anodic oxidation, electrodeposition, co-precipitation. The physical method includes, but are not limited to, one or more of solution methods (such as spin-coating, printing, doctor-blading, dip-coating, immersion-drawing, spray-coating, roll-coating, casting, slot-die coating, or stripe coating, etc.), vapor deposition methods (such as thermal evaporation, electron beam evaporation, magnetron sputtering, or multi-arc ion plating, etc.), and deposition methods (such as physical vapor deposition, atomic layer deposition, pulsed laser deposition, etc.).

One embodiment of the present disclosure provides a pixel lighting control method for the display device, the display device comprises a plurality of pixels arranged in an array, and each pixel comprises a red light sub-pixel, a green light sub-pixel, a first blue light sub-pixel and a second blue light sub-pixel arranged in an array, and the control method comprises:

Controlling the first blue light sub-pixel or the second blue light sub-pixel to emit light according to the target blue light brightness value and the preset blue light brightness value.

In the present embodiment, the step of controlling the first blue light sub-pixel or the second blue light sub-pixel to emit light according to the target blue light brightness value and the preset blue light brightness value comprises:
Starting the first blue light sub-pixel to emit light when the target blue light brightness value is greater than or equal to the preset blue light brightness value; or,
Starting the second blue light sub-pixel to emit light when the target blue light brightness value is lower than the preset blue light brightness value.

It should be noted that the preset blue light brightness value refers to 70%-90% of the highest blue light brightness value of the product. For example, when the display device is applied to TV, and the normal brightness of TV products is 100 nits, the range of the preset blue light brightness value is 70-90 nits.

In the present embodiment, the R, G, B1, and B2 sub-pixels are all quantum dot-based electroluminescent devices, the B1 sub-pixel is a high-efficiency blue light quantum dot device, which is lighted when high brightness is required; the B2 sub-pixel is long-lifetime blue light quantum dot devices, which is lighted when low brightness is required. In this way, by selecting blue light quantum dot devices with different characteristics, both high luminous efficiency and long lifetime of the device can be realized without affecting the display effect of the full-color display device.

In the present embodiment, the B1 sub-pixel is a high-efficiency blue light quantum dot device. In one embodiment, the current efficiency of the first blue light sub-pixel (denoted as C.E._{B1}) is ≥8 cd/A, that is, C.E._{B1}≥8 cd/A.

In one embodiment, the ratio of the current efficiency of the first blue light sub-pixel to the current efficiency of the second blue light sub-pixel (denoted as C.E._{B2}) is ≥1.5, that is, C.E._{B1}/C.E._{B2}≥1.5. In one embodiment, 3≥C.E._{B1}/C.E._{B2}≥1.5.

In the present embodiment, the B2 sub-pixel is a long-lifetime blue light quantum dot device. In one embodiment, the lifetime of the second blue light sub-pixel (denoted as L.T._{B2}) is ≥200 h@1000 nits, that is, L.T._{B2}≥200 h@1000 nits.

In one embodiment, the ratio of the lifetime of the second blue light sub-pixel to the lifetime of the first blue light sub-pixel (denoted as L.T._{B1}) is ≥1.5, that is, L.T._{B2}/L.T._{B1}≥1.5. In one embodiment, 3≥L.T._{B2}/L.T._{B1}≥1.5.

The selection of the structure and the material, and other details of the display device are described above, and will not be repeated here.

It should be understood that the application of the present disclosure is not limited to the above embodiments, and those skilled in the art may make improvements or transformations based on the above descriptions, and all these improvements and transformations shall fall within the protection scope of the appended claims of the present disclosure.

1. A display device, comprising a plurality of pixels arranged in array, wherein each pixel comprises a red light sub-pixel, a green light sub-pixel, a first blue light sub-pixel and a second blue light sub-pixel arranged in array;
the display device further comprises: a starting module, configured to start the first blue light sub-pixel to emit light when a target blue light brightness value is greater than a preset blue light brightness value, and start the second blue light sub-pixel to emit light when the target blue light brightness value is lower than the preset blue light brightness value.

2. The display device according to claim 1, wherein a current efficiency of the first blue light sub-pixel is ≥8 cd/A.

3. The display device according to claim 1, wherein a ratio of a current efficiency of the first blue light sub-pixel to a current efficiency of the second blue light sub-pixel is ≥1.5.

4. The display device according to claim 1, wherein a lifetime of the second blue light sub-pixel is ≥200 h@1000 nits.

5. The display device according to claim 1, wherein a ratio of a lifetime of the second blue light sub-pixel to a lifetime of the first blue light sub-pixel is ≥1.5.

6. The display device according to claim 3, wherein the ratio of the current efficiency of the first blue light sub-pixel to the current efficiency of the second blue light sub-pixel is greater than or equal to 1.5 and less than 3.

7. The display device according to claim 6, wherein a ratio of a lifetime of the second blue light sub-pixel to a lifetime of the first blue light sub-pixel is greater than or equal to 1.5 and less than 3.

8. The display device according to claim 1, wherein the display device further comprises:
a comparison module, configured to compare the target blue light brightness value with the preset blue light brightness value;
a control module, configured to control the first blue light sub-pixel or the second blue light sub-pixel to emit light according to a comparison result.

9. The display device according to claim 8, wherein the control module is a multiplexer.

10. The display device according to claim 1, wherein the red light sub-pixel comprises a first anode, a first hole injection layer, a first hole transport layer, a red light quantum dot light-emitting layer, a first an electron transport layer, a first cathode and a first light extraction layer stacked sequentially;
the green light sub-pixel comprises a second anode, a second hole injection layer, a second hole transport layer, a green light quantum dot light-emitting layer, a second electron transport layer, a second cathode, and a second light extraction layer stacked sequentially;
the first blue light sub-pixel comprises a third anode, a third hole injection layer, a third hole transport layer, a first blue light quantum dot light-emitting layer, a third electron transport layer, a third cathode and a third light extraction layer stacked sequentially;
the second blue light sub-pixel comprises a fourth anode, a fourth hole injection layer, a fourth hole transport layer, a second blue light quantum dot light-emitting layer, a fourth electron transport layer, a fourth cathode and a fourth light extraction layer stacked sequentially.

11. The display device according to claim 10, wherein a thickness of the red light quantum dot light-emitting layer is 5 nm-50 nm;
or, a thickness of the green light quantum dot light-emitting layer is 5 nm-50 nm;
or, a thickness of the first blue light quantum dot light-emitting layer is 5 nm-50 nm;
or, a thickness of the second blue light quantum dot light-emitting layer is 5 nm-50 nm.

12. The display device according to claim 10, wherein the red light quantum dot, green light quantum dot, first blue light quantum dot and second blue light quantum dot are independently selected from one or more of a binary phase, a ternary phase, and a quaternary phase quantum dot.

13. The display device according to claim 12, wherein the binary phase quantum dot is one or more of CdS, CdSe, CdTe, InP, AgS, PbS, PbSe, and HgS; or the ternary phase quantum dot is one or more of ZnCdS, CuInS, ZnCdSe, ZnSeS, ZnCdTe, and PbSeS, or the quaternary phase quantum dot is one or more of ZnCdS/ZnSe, CuInS/ZnS, ZnCdSe/ZnS, CuInSeS, ZnCdTe/ZnS, and PbSeS/ZnS.

14. (canceled)

15. (canceled)

16. The display device according to claim 1, wherein an emission wavelength of the red light quantum dot is 610-625 nm, and/or an emission wavelength of the green light quantum dot is 525-550 nm, and/or an emission wavelength of the first blue light quantum dot is 450-480 nm, and/or an emission wavelength of the second blue light quantum dot is 450-480 nm.

17. A pixel lighting control method for a display device, wherein the display device comprises a plurality of pixels arranged in array, and each pixel comprises a red light sub-pixel, a green light sub-pixel, a first blue light sub-pixel and a second blue light sub-pixel arranged in array, the control method comprises:
controlling the first blue light sub-pixel or the second blue light sub-pixel to emit light according to a target blue light brightness value and a preset blue light brightness value.

18. The pixel lighting control method for the display device according to claim 17, wherein the step of controlling the first blue light sub-pixel or the second blue light sub-pixel to emit light according to a target blue light brightness value and a preset blue light brightness value comprises:
starting the first blue light sub-pixel to emit light when the target blue light brightness value is greater than or equal to the preset blue light brightness value; or,
starting the second blue light sub-pixel to emit light when the target blue light brightness value is lower than the preset blue light brightness value.

19. The pixel lighting control method for the display device according to claim 17, wherein a current efficiency of the first blue light sub-pixel is ≥8 cd/A.

20. The pixel lighting control method for the display device according to claim 17, wherein a ratio of a current efficiency of the first blue light sub-pixel to a current efficiency of the second blue light sub-pixel is greater than or equal to 1.5 and less than 3.

21. The pixel lighting control method for the display device according to claim wherein a lifetime of the second blue light sub-pixel is ≥200 h@1000 nits.

22. The pixel lighting control method for the display device according to claim wherein a ratio of a lifetime of the second blue light sub-pixel to a lifetime of the first blue light sub-pixel is greater than or equal to 1.5 and less than 3.
